(19) United States
(12) Patent Application Publication
(10) Pub. No.: US 2021/0256413 A1
(43) Pub. Date: Aug. 19, 2021

(54) QUANTUM COMPUTER ARRAYS

(71) Applicant: The University of Melbourne, The University of Melbourne, Victoria (AU)

(72) Inventors: Lloyd Christopher Leonard Hollenberg, Melbourne (AU); Charles David Hill, Melbourne (AU); Muhammad Usman, Melbourne (AU)

(21) Appl. No.: 17/270,390

(22) PCT Filed: Aug. 23, 2019
(86) PCT No.: PCT/AU2019/050889

§ 371 Date: Feb. 22, 2021

(30) Foreign Application Priority Data
Aug. 23, 2018 (AU) 2018903094

(51) Int. Cl. G06N 10/00; H01L 39/22; H01L 27/18

(52) U.S. Cl. CPC G06N 10/00; H01L 27/18; H01L 39/228

(57) ABSTRACT

This disclosure relates to quantum computer arrays. In particular, a quantum processor comprises an array of source lines, drain lines and gate lines intersecting each other to define processor cells. Each of the processor cells comprise a first qubit, a second qubit and an electron confinement region disposed between the first qubit and the second qubit. A control circuit controls loading and unloading of an electron into the electron confinement region. The loading of the electron into the confinement region enables exchange interaction between electrons of the first qubit and the second qubit, and the unloading of the electron out of the electron confinement region suppresses exchange interaction between the electrons of the first qubit and the second qubit.

### CROSS-REFERENCE TO RELATED APPLICATIONS

The present application claims priority from Australian Provisional Patent Application No 2018903094 filed on 23 Aug. 2018, the contents of which are incorporated herein by reference in their entirety.

### TECHNICAL FIELD

This disclosure relates to quantum computer arrays.

### BACKGROUND

Quantum computers face a range of different challenges due to the nature of the underlying physics. For example, placing two qubits too close to each other would make the manufacturing process impractical. In particular, it would be difficult to manufacture electrodes or wires at a pitch of less than 20 nm.

Australian patent application 2015252050 entitled “A Quantum Processor”, discloses a quantum processor where quantum information is stored in the nuclear spin of donor atoms and the donor atoms interact via dipole interaction. Since dipole interaction has a relatively long range of over 30 nm, the donor atoms can be located apart from each other by a distance that allows the manufacturing of electrodes and wires using existing processes. Therefore, this provides a technology that is practicably achievable under realistic circumstances.

However, one drawback with the above quantum processor is that the dipole interaction is relatively slow and in the order of 1-100 kHz. FIG. 1 illustrates magnetic dipole interaction between a first magnetic dipole 101 of a first electron and a second magnetic dipole 102 of a second electron. The dipole interaction is indicated by dashed arrow 103. Since the dipole interaction is caused by a magnetic field that decreases across a relatively long distance, the dipole interaction is relatively long range and occurs even when the dipoles 101 and 102 are spaced relatively far from each other.

Another solution would be to use electrons that interact via exchange interaction instead of dipole interaction. FIG. 2 illustrates two electrons 201 and 202 in a simplified representation. When electrons 201 and 202 are brought relatively close together, their wave functions (as indicated by the circles in FIG. 2) overlap 203. When this happens, an effect that is also the underlying cause of the Pauli principle takes place. The Pauli principle states that two electrons in an orbital with the same energy cannot have the same spin but must have opposite spin. So if electrons 201 and 202 are sufficiently close to each other and have the same energy, this principle emerges. This leads to an effective spin interaction between the electrons which is referred to as exchange interaction.

While this exchange interaction occurs in the range of 10-1000 MHz, which is significantly faster than dipole interaction, the electrons need to be so close to each other that manufacturing the device becomes a real challenge.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

A quantum processor comprises:

an array of multiple source lines, drain lines and gate lines intersecting each other to define multiple processor cells;

each of the multiple processor cells comprising a first qubit, a second qubit and an electron confinement region disposed between the first qubit and the second qubit,

a control circuit to control loading and unloading of an electron into the electron confinement region, wherein

the loading of the electron into the confinement region enables exchange interaction between electrons of the first qubit and the second qubit, and
the unloading of the electron out of the electron confinement region suppresses exchange interaction between the electrons of the first qubit and the second qubit.

A distance between the first qubit and the second qubit may be greater than the range of exchange interaction between the electrons of the first qubit and the second qubit. The distance between the first qubit and the second qubit may be greater than 15 nm. A distance between the first qubit and the second qubit may be less than twice the range of exchange interaction between the electrons of the first qubit and the second qubit. A distance between either qubit and the electron confinement region may be less than the range of exchange interaction between the electron loaded into the electron confinement region and the electrons of either qubit. The distance between the first qubit and the electron confinement region may be greater than the distance between the electron confinement region and the second qubit.

The first qubit and the second qubit may be formed by respective donor atoms. Strain may be applied to reduce variations in exchange coupling due to placement variations of the donor atoms. The first qubit and the second qubit may be formed by respective quantum dots. The electron confinement region may be formed by a donor atom or a quantum dot.

Quantum information may be stored in the electron spin of the first qubit and the second qubit. Quantum information may be stored in the electron spin of first qubit and the second qubit.

Hyperfine interaction may facilitate a transfer of quantum information between tire electrons and nuclei of the respective first qubit and second qubit. The first qubit may be configured as an ancilla qubit and the second qubit may be configured as a data qubit to perform quantum error correction.

The quantum processor may further comprise a tunnelling reservoir device to facilitate the loading of the electron into the electron confinement region by tunnelling of the electron from a source electrode into the electron confinement region and to facilitate the unloading of the electron out of the electron confinement region by tunnelling of the electron from the electron confinement region into a drain electrode. The tunnelling reservoir device may be a single electron transistor.

The control circuit may be configured to operate the quantum processor at a frequency that is higher than tire frequency of dipole interactions between the first qubit and the second qubit.

The control circuit may be configured to operate the quantum processor at a frequency of at least 1 MHz.

The first qubit and the second qubit may remain loaded with an electron during operation of the quantum computer.

The first qubit and the second qubit of the multiple processor cells may form multiple qubits and the multiple qubits may be located at respective sites in a lattice and the control circuit is adapted to perform a method comprising:

determining multiple non-overlapping pulse sequences, each pulse sequence being configured to operate one or more of the multiple qubits selected by the respective site in die lattice, wherein determining the multiple non-overlapping pulse sequences is based on possible discrete values of the respective site in the lattice: and

applying the multiple non-overlapping pulse sequences to the multiple qubits in parallel to thereby operate more than one of die multiple qubits in parallel.

Determining the multiple non-overlapping pulse sequences may be based on pulse engineering.

A method for operating a quantum computer comprises:

loading of an electron into a confinement region disposed between a first qubit and a second qubit to enable exchange interaction between electrons of the first qubit and the second qubit; and

unloading of the electron out of the electron confinement region to suppress exchange interaction between the electrons of the first qubit and the second qubit.

### BRIEF DESCRIPTION OF DRAWINGS

FIG. 1 illustrates dipole interaction according to the prior art.

FIG. 2 illustrates two electrons in a simplified representation according to the prior art.

An example will now be described with reference to the following drawings:

FIG. 3 illustrates a basic processor cell of a quantum processor.

FIG. 4 illustrates two qubits with their corresponding wave function where an electron confinement region between them is unloaded.

FIG. 5 illustrates two qubits with their corresponding wave function where an electron confinement region between them is loaded.

FIG. 6 illustrates a quantum processor formed by multiple processor cells as shown in FIG. 3.

FIG. 7 is a perspective view of the quantum processor in FIG. 6.

FIG. 8 and FIG. 9 provide examples of dimensions of the individual elements of the quantum processor in FIGS. 6 and 7.

FIG. 10 illustrates a crystal lattice and two sites of donors.

FIG. 11 illustrates potential lattice sites for two donors.

FIG. 12 illustrates steps for determining a pulse sequence.

FIGS. 13 and 14 illustrate Gradient Ascent Pulse Engineering (GRAPE) pulse sequences.

FIG. 15 a illustrates a quantum circuit used to measure X-stabilisers.

FIG. 15b illustrates a quantum circuit used to measure Z-stabilisers.

FIG. 16 illustrates the corresponding architecture labelled with ‘X’ and ‘Z’ accordingly.

FIG. 17 illustrates two overlapping pulse sequences.

FIG. 18a illustrates a quantum processor with three sets of CNOT gates.

FIG. 18b illustrates the semi-parallel application of grape sequences.

FIG. 19 illustrates a method for operating a quantum processor

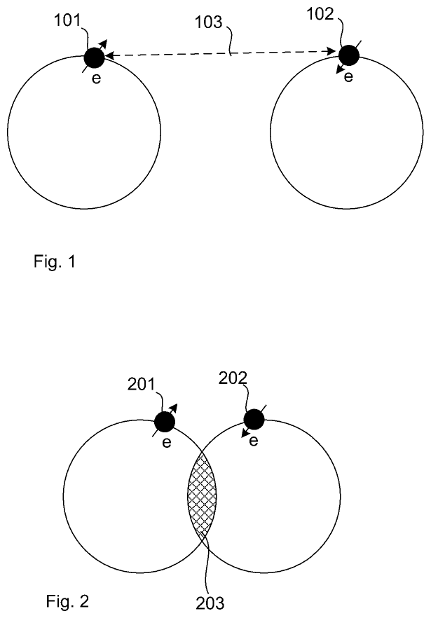

### DESCRIPTION OF EMBODIMENTS

This disclosure provides a quantum computer that utilises exchange interactions to increase the speed of the quantum operations but at the same time keeps the distance between the qubits sufficiently large to allow fabrication of the processor including the control lines using a practical minimum pitch. In particular, the quantum computer comprises an electron confinement region that can be loaded and unloaded to switch the exchange interaction between the qubits on and off, respectively. Thereby, the range of exchange interaction is effectively extended and also switchable to implement various qubit operations.

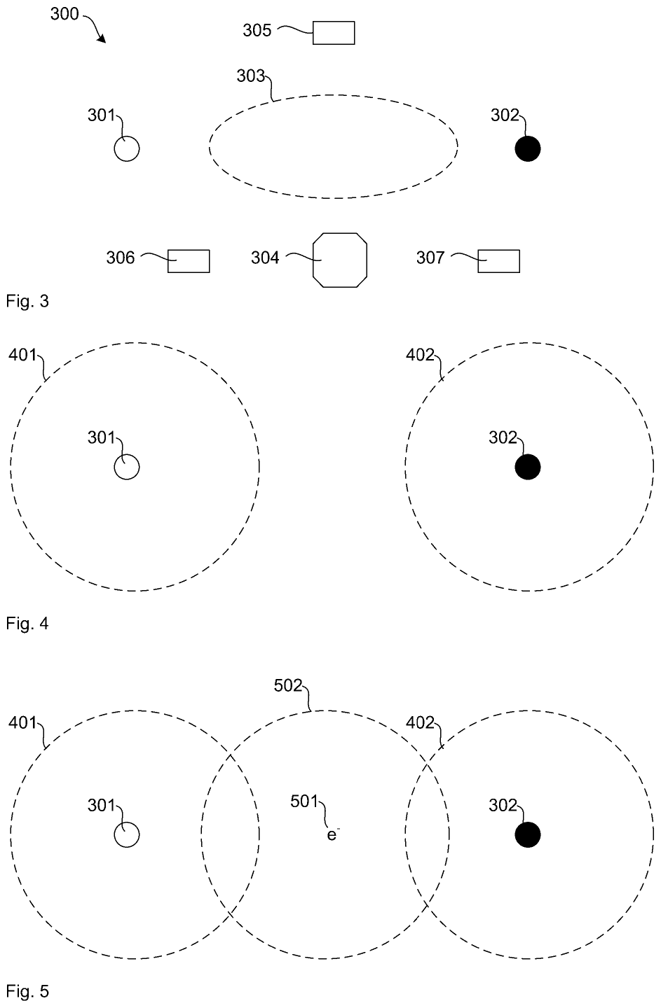

FIG. 3 illustrates a basic processor cell 300 comprising a first qubit 301 and a second qubit 302 as well as an electron confinement region 303. The electron confinement region 303 can be loaded and unloaded by a control circuit comprising a tunnelling reservoir device, such as a single electron transistor that includes an island 304 with an electrical potential that is controllable via a gate electrode 305. When the voltage applied on gate electrode 305 lowers the electrical potential of island 304, an electron can tunnel from a source electrode 306 into island 304 and then into electron confinement region 303. This loads the electron into the confinement region 303. Conversely, by switching the voltage applied on the gate electrode 305, the electron in the confinement region tunnels back through island 304 into drain electrode 307, which unloads the electron out of the confinement region 303. The control circuit may further comprise drivers that drive the electrodes/wires and a processor that determines the control signals to drive the electrodes/wires to perform quantum operations using the quantum processor. For example, the control circuit may create control signals that adjust the energy levels of the qubits so that quantum information can be stored on selected qubits by applying an RF, MW or optical signal to the qubits. The control signals may then facilitate operation of the quantum operation, that is, evolution of the quantum states of the qubits during an evolution time and readout of the resulting qubit state as the result of the operation.

FIG. 4 illustrates again the first qubit 301 and the second qubit 302 as well as a first wave function 401 of the first qubit 301 and a second wave function 402 of second qubit 302. At this moment in time, the electron has been unloaded out of the electron confinement region, which is why it is not shown in FIG. 4. As can be seen, the first wave function 401 does not overlap with the second wave function 402. As a result, the exchange interaction between first qubit 301 and second qubit 302 is essentially turned off. While the nuclei of qubits 301 and 302 still interact via dipole coupling, this effect is relatively slow and negligible if the quantum processor is operated at a speed that is well above the dipole coupling speed. For example, the quantum processor is operated at 1 MHz or between 10 and 1000 MHz, which means encoding quantum information onto the qubits, performing a qubit operation and reading the result of the operation from the qubit occurs at this rate (which is significantly higher than the speed of dipole interactions, such as at least ten times higher).

FIG. 5 illustrates the first qubit 301 and the second qubit 302 with their respective wave functions 401 and 402. In contrast to FIG. 4, an electron 501 has been loaded into the electron confinement region and a corresponding third wave function 502 is shown. Now, the first wave function 401 overlaps with the third wave function 502, which, in turn, overlaps with the second wave function 402. As a result, the exchange interaction between the first qubit 301 and the second qubit 302 is essentially turned on via the electron 501. FIG. 5 also shows that the qubits 301 and 302 are located at a distance apart from each other, which would normally not allow exchange interactions except when electron confinement region 303 is loaded. This relatively large distance allows the manufacturing of control lines as described below while at the same time facilitating fast exchange interactions.

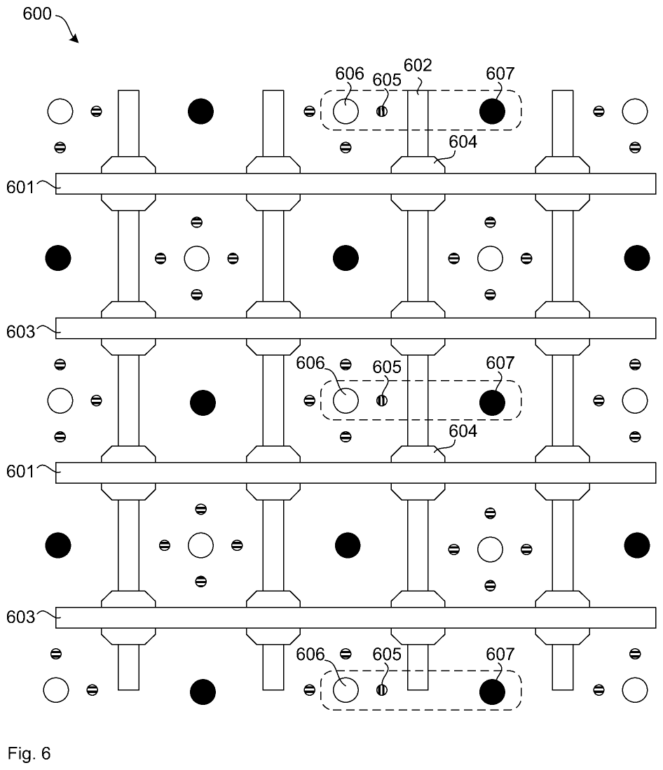

FIG. 6 illustrates a quantum processor 600 formed by multiple processor cells as shown in FIG. 3. In particular, quantum processor comprises a criss-cross array of multiple source lines, drain lines and gate lines intersecting each other to define the multiple processor cells. In FIG. 3 not all elements are labelled with a reference numeral simply to improve the clarity of the figure. In particular, in accordance with the previous figures first qubits are shown as white filled circles while second qubits are shown as black filled circles.

The proposed architecture is particularly useful in the context of quantum error correction where the first qubit 301 can be referred to as ancilla qubit 301 and the second qubit is referred to as data qubit 302. This nomenclature will be used in the following description noting that the architecture may be used in other fields where both qubits are general qubits or other qubits with specific functionality. So, black circles in FIG. 6 are data qubits while white circles are ancilla qubits in this example.

It is further noted that the electron confinement region can be implemented in various different ways including quantum dots and donor atoms. Importantly, any implementation may be possible that provides confinement to an electron such that exchange interactions between the confined electron and adjacent qubit electrons can occur. The following example uses donor atoms (such as phosphorous donor atoms) for ancilla and qubits as well as electron confinement regions and the latter is also referred to as coupling donor and indicated by small circles in FIG. 6.

Since the various wires/lines are identical and symmetrical, each line can take different functionality in the sense that it can function as a drain line, source line and gate line. In one example, however, the top layer of lines, which are the horizontal lines here, are used as source lines while the bottom layer of lines, which are the vertical lines here, are used as the drain lines. In the scenario of FIG. 6, three lines 601 act as source lines and line 602 acts as a drain line. Lines 603 act as gate lines. The remaining lines are not active (connected to a neutral voltage, such as 0V). This activates islands 604 and loads electrons on respective coupler donors 605 as indicated by their vertical shading Horizontally shaded coupler donors are unloaded. The loading of coupler donors 605 facilitates exchange interactions between ancilla qubits 606 and data qubits 607 as described above with reference to FIGS. 4 and 5 and as indicated by the dashed rectangles in FIG. 6.

In one example, the wire spacing is about 14+18=32 nm in a square lattice. This means that the spacing of the coupler donor 605 is asymmetric in the sense that coupler donor is closer to the ancilla qubit 606 than the data qubit 607, such as 14 nm from the ancilla qubit 606 and 18 nm from the data qubit 607. However, other dimensions are equally possible. This asymmetry provides more flexibility in controlling the quantum processor because the respective interactions can be tuned separately. Further, the asymmetric coupling allows to distinguish between ancilla qubit 606 and data qubit 607 in a CNOT gate, for example.

In some examples, the distance between the ancilla qubit 606 and the data qubit 607 is greater than the range of exchange interactions between the two, which is greater than 20 nm. On the other hand, the distance between the ancilla qubit 606 and the data qubit 607 is less than twice the range of exchange interactions, that is, less than 40 nm. Further, the distance between the coupler donor 605 and any of the qubits 606 and 607 is less than the range of exchange interactions, that is, less than 20 nm. While these example distances are provided for phosphorous in silicon, other materials and other technologies may have different ranges of exchange interactions.

It is further noted that the interaction between the reservoirs islands 604 and the qubits 606/607 is in the order of MHz while the interaction between the reservoir islands 604 and the coupler donors 605 is significantly greater than that interaction. This is because the distance to the qubits 606/607 is about 1.75 times the distance to the coupler 605 and the exchange interaction drops rapidly with distance. This means that the coupler 605 can be loaded/unloaded relatively quickly without affecting the load on the qubits 606/607. In one example, the qubits 606/607 always remain loaded with an electron. This has the advantage that phase error is reduced that would otherwise occur by loading and unloading electrons onto the qubits over a period of time that is practically required to perform this operation. The quantum information may then be stored on the qubit electron spin or may be transferred between the qubit electron spin and the qubit nuclear spin through hyperfine interaction between them. In effect, the quantum information can be ‘frozen’ for read-out by transferring the information onto the nuclear spin.

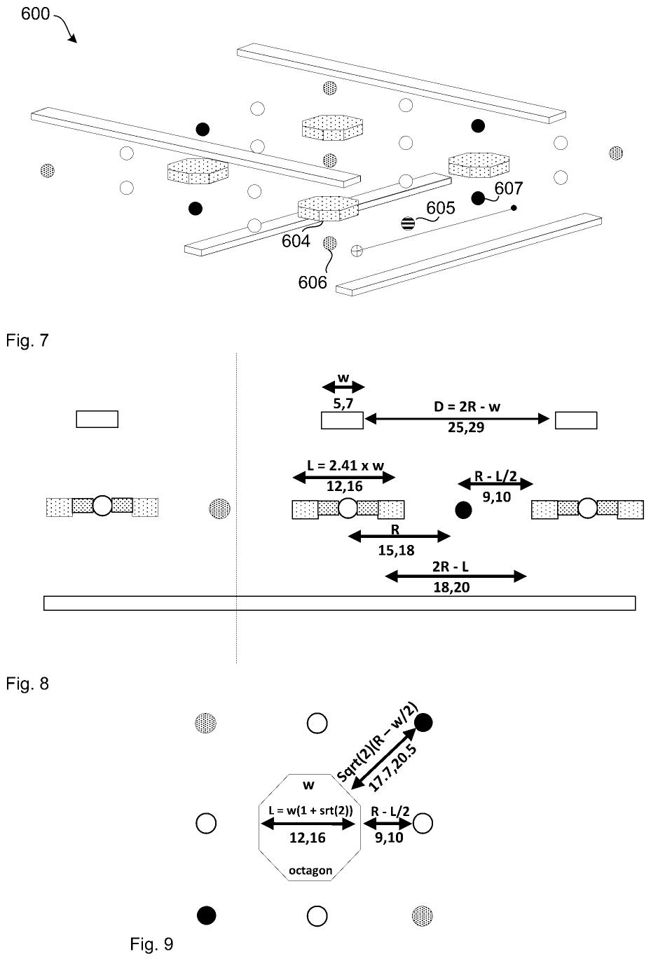

FIG. 7 is a perspective view of the quantum processor 600 showing the vertically stacked layers. FIG. 8 and FIG. 9 provide examples of dimensions of the individual elements noting that other dimensions may equally be possible. In one example, there is an introduction of 5% biaxial strain in the silicon crystal. This strain can be applied to reduce or smooth out variations in the exchange coupling due to donor placement variations in a case where the qubits 301/302 and the confinement region are implemented as donor atoms.

It is further noted that no phase matched loading is necessary as the loading onto coupler is not sensitive to phase variation, but assumed to be fast compared to coupling strength. The overall timescale for CNOT gates with the described architecture is potentially in a range of 500-1000 ns, so up to 1000× faster than in current designs.

While the above examples show a single coupler donor, it is possible to have a chain of multiple coupler donors between the ancilla qubit 606 and the data qubit 607. It is also possible to use a quantum dot as an electron confinement area (i.e. well) instead of the coupler donor. In this sense, all combinations of quantum dots (QD) and donor atoms for the first qubit 301, confinement region 303 and second qubit 302 are possible including; donor-donor-donor, QD-QD-QD, donor-QD-donor, QD-donor-QD.

The disclosed architecture may be formed in isotopically purified silicon (²⁸Si) substrate. A plurality of phosphorus atoms are embedded in the silicon lattice to act as donors for qubits and couplers. A possible technique to manufacture the architecture is to start from a pure silicon wafer and fabricate the structures on each plane exploiting the lithographic capabilities of a scanning tunnelling microscope together with silicon epitaxy. In operation, the entire device may be cooled to the mK regime, operates in a magnetic field of approximately B=2T with an externally applied (global) RF and MW control.

As described above, the proposed architecture relies on exchange interaction between electrons and the strength of this exchange interaction depends strongly on the distance between the donors (i.e. the overlap of their wave functions). In particular, a variation of the location of a donor by a single site in the lattice causes a significant change in the strength of exchange interaction. It is therefore a challenge to characterise and control quantum processor 600 because the donors may be placed in different lattice sites due to uncontrollable manufacturing variations.

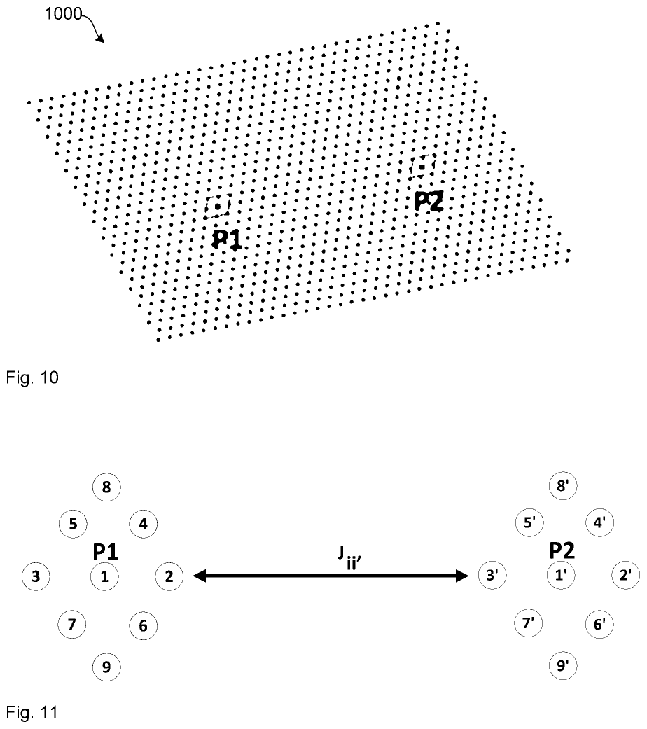

FIG. 10 illustrates a lattice 1000 and two sites of donors indicated at ‘P1’ and ‘P2’, respectively. As a result of process variations, these sites can change in all directions. In one example, these changes are considered only in the in-plane directions, that is, in two dimensions. FIG. 11 illustrates nine potential lattice sites for P1 and nine potential lattice sites for P2. The interaction Jᵢᵢ between them can be characterised by any of the possible combinations of lattice sites and the corresponding difference between the donors. The following table provides example values, around 15 distinct J value compared to 81 total positions, of exchange coupling between donors for various separations and one lattice site variations using million atom tight-binding calculations:

| | | Exchange Interaction in the units of MHz | | | | | | |
|---|---|---|---|---|---|---|---|---|
| | | Separation between P1 and P2 donors along the (100) direction | | | | | | |
| Prob | Positi | 10 nm | 12 nm | 14 nm | 15 nm | 18 nm | 20 nm | 25 nm |
| 0.11 | J₁₁ | 49399.3148 | 3537.4132 | 1390.7917 | 887.0558 | 104.2636 | 9.7969 | 0.3432 |
| 0.05 | J₁₂ | 23751.6732 | 6157.9489 | 875.2997 | 306.2048 | 41.0977 | 16.5777 | 0.1565 |
| 0.05 | J₁₃ | 63271.2872 | 8400.2314 | 2954.5756 | 568.3980 | 19.3924 | 23.8287 | 0.4649 |
| 0.15 | J₁₆ | 34551.2596 | 4427.0125 | 1219.1723 | 544.2394 | 70.7599 | 4.8498 | 0.2410 |
| 0.01 | J₂₃ | 82654.3014 | 7884.4229 | 1841.8874 | 657.7768 | 77.5358 | 23.2235 | 0.4024 |
| 0.16 | J₂₆ | 43613.9176 | 10565.6716 | 1756.4779 | 998.2582 | 55.0401 | 10.2208 | 0.3222 |
| 0.01 | J₃₂ | 15969.1468 | 3783.0698 | 881.9690 | 258.7607 | 45.0642 | 9.9137 | 0.1001 |
| 0.05 | J₃₆ | 20752.3131 | 2461.7377 | 2111.4195 | 195.7186 | 51.3846 | 14.3387 | 0.1371 |
| 0.05 | J₄₃ | 72989.3054 | 10618.7688 | 2659.7639 | 105.4182 | 71.5528 | 3.1374 | 0.5724 |
| 0.10 | J₄₆ | 42968.9634 | 10273.1928 | 1376.7070 | 475.3144 | 49.4468 | 11.2641 | 0.3034 |
| 0.06 | J₄₇ | 69183.9764 | 4644.2631 | 2589.4557 | 752.2352 | 161.7125 | 13.3756 | 0.5172 |
| 0.05 | J₄₉ | 57078.8460 | 4644.2631 | 1151.8549 | 574.9414 | 128.5184 | 19.0246 | 0.4191 |
| 0.07 | J₅₆ | 10607.6828 | 4993.9943 | 1323.2797 | 741.3605 | 63.2716 | 6.1940 | 0.0709 |
| 0.05 | J₅₉ | 20549.3090 | 3676.6431 | 318.5620 | 672.0522 | 35.7696 | 4.3394 | 0.1425 |
| 0.02 | J₈₉ | 32729.2174 | 8075.3924 | 1941.2775 | 453.4773 | 32.1228 | 14.6391 | 0.2390 |

In order to address this challenge, a pulse sequence can be designed that controls the qubits in parallel despite variations in the relative placement of the qubits on lattice sites. Designing the pulse sequence may comprise determining multiple non-overlapping pulse sequences for different possible discrete values of the respective site in the lattice. Applying the non-overlapping pulse sequences to the multiple qubits in parallel would then operate more than one of the multiple qubits in parallel.

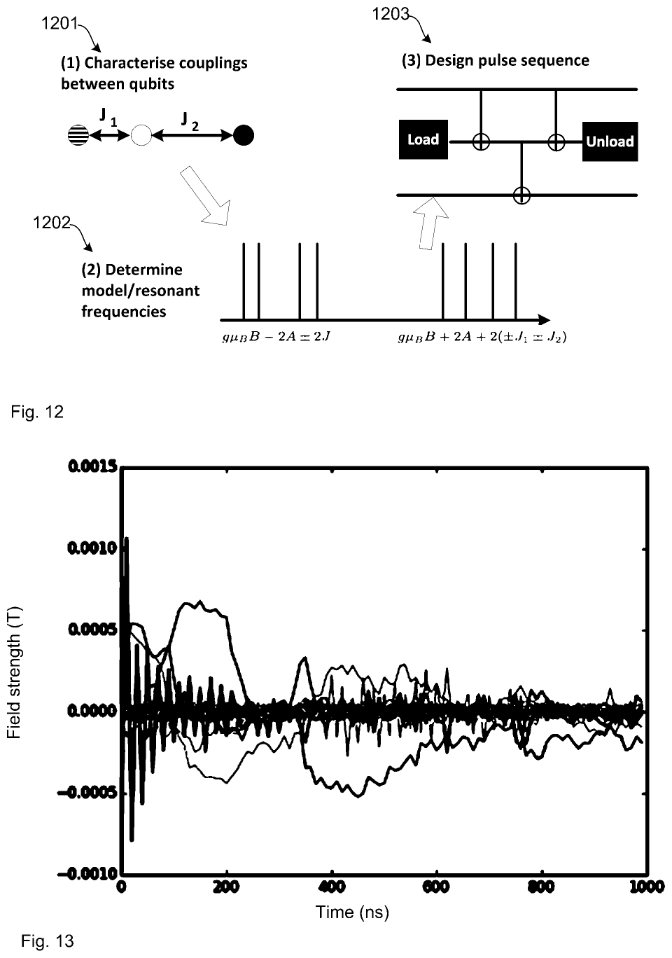

It is possible to perform Gradient Ascent Pulse Engineering (GRAPE) in the design of the CNOT gate between data-ancilla mediated by their J interactions with the coupler qubit when it is occupied. In particular, FIG. 12 illustrates the steps of characterising 1201 couplings between qubits, determining 1202 model/resonant frequencies and design 1203 a pulse sequence. It is noted that in the strong coupling regime transitions are not so easily identifiable with individual spins (Eigenstates become dressed) and additional transitions are ‘allowed’. This may be solved numerically, designing pluses by gradient ascent optimisation. In other words the overall CNOT gate can be implemented by numerically engineering the applied resonant MW/RF control for each distinct J1 and J2 scenario. It is possible to specify that all CNOT gates take the same amount of time no matter the actual values of J1 and J2. A different GRAPE sequence is determined for a given qubit interaction location, but each sequence is designed to give a CNOT gate of a common duration, in this case 1 μs.

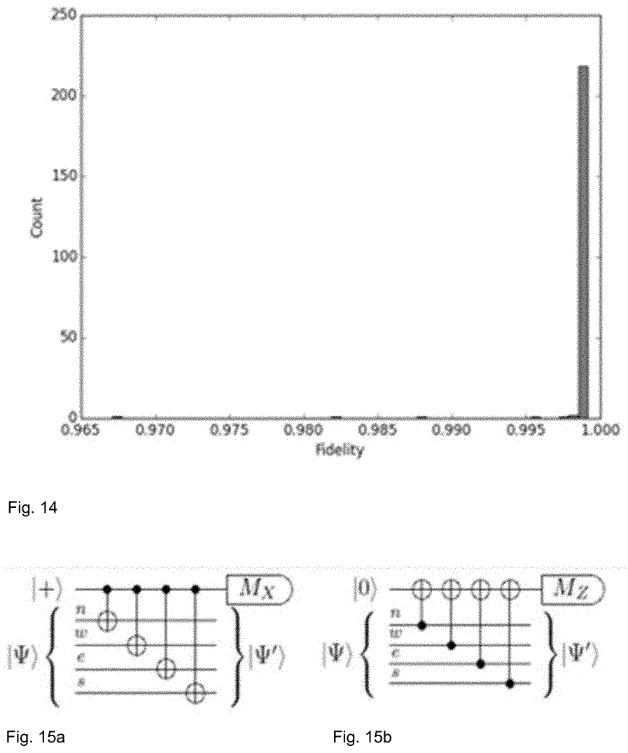

FIGS. 13 and 14 illustrate GRAPE sequences designed for the whole set of exchange couplings based on data-coupler and ancilla-coupler target separations of 18 nm and 14 nm respectively. FIG. 13 illustrates examples controls from GRAPE pulse sequence with a total time of 1 μs, fidelity of 99.9%, J₁=1323 MHz and J₂=19 MHz. FIG. 14 shows that for the separations of 14 nm and 18 nm it is possible to find high fidelity 1 μs plus sequences, for each of the 225 different locations of the three phosphorus atoms (1P-1P-1P). This indicates that the quantum processor can be operated at a speed of at least 1 MHz.

The above architecture has much faster CNOT gates (up to 1000× faster) and simpler operation (no phase matched loading). To operate in parallel as per the surface code it may not be possible to operate all CNOT gates in parallel. However, it is possible to determine the set of CNOT gates of size Ng elements which can be run in parallel and hence the operation sequence that involves an extra Ng steps in the QEC protocol.

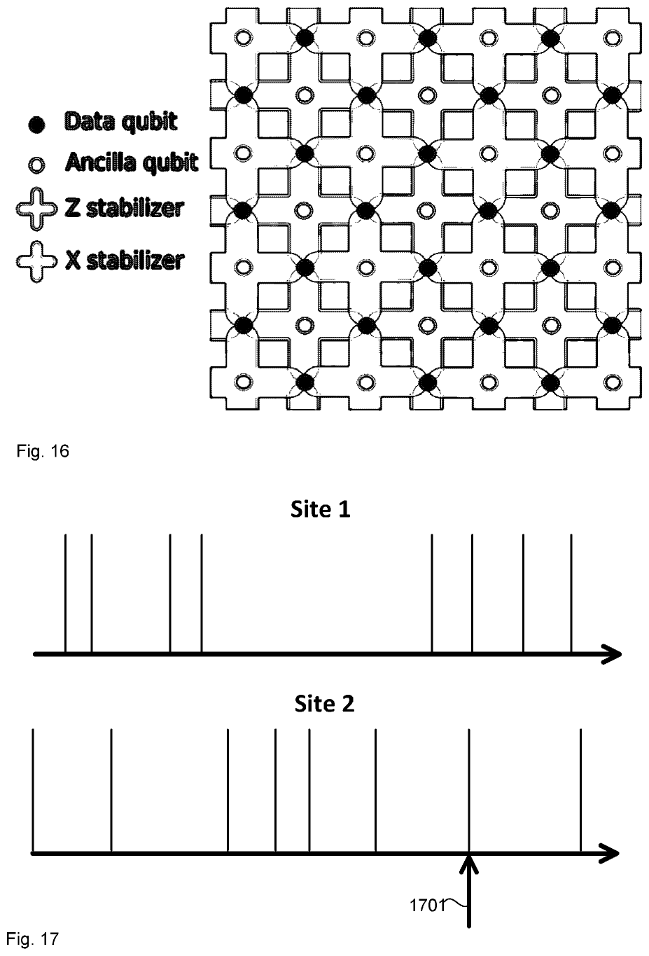

As per background on the surface code and how it uses operations run in parallel across the architecture, FIG. 15 a illustrates a quantum circuit used to measure X-stabilisers and FIG. 15b illustrates a quantum circuit used to measure Z-stabilisers. FIG. 16 illustrates the corresponding architecture labelled with ‘X’ and ‘Z’ accordingly.

FIG. 17 illustrates two pulse sequences for Site 1 and Site 2 and a conflict indicated by arrow 1701 where the two pulse sequences overlap. CNOT gates can be run in parallel provided there are no overlapping resonant frequencies as in FIG. 17, where the resonant frequencies interfere with the operation of the other qubits. This means that many but not all CNOT gates cannot be run in parallel.

The above explanations can be generalised to the case of a generic quantum computer where there are natural variations in the qubit-qubit interaction strengths and/or control. In the generic case, each CNOT is implemented independently using the local control lines for each qubit pair. As the control may take a different amount of time for each CNOT, scheduling and keeping track of phases accumulated may become problematic, potentially a bottleneck issue. However, a given inherent level of uniformity can be assumed in fabrication (a generic goal) and in that case, it may be possible to create a finite set of CNOT sequences (set size N_{g}) designed using e.g. GRAPE to be of equal temporal length, which can be scheduled to be implemented as described above in N_{g} steps over the qubit array in a semi-parallel fashion.

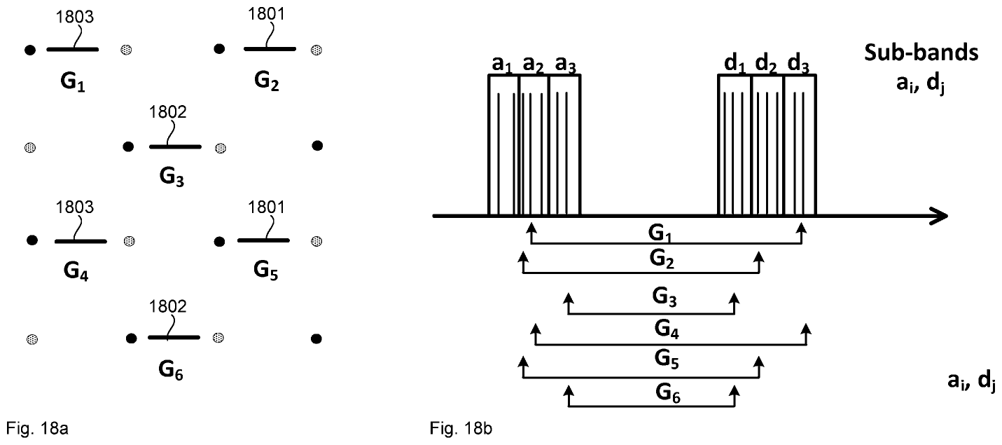

FIG. 18a illustrates a quantum processor with three sets of CNOT gates 1801, 1802, 1803. It is noted that the CNOT gates are implemented between ancilla and data qubits as described above. It is further noted that in FIG. 18a the coupler donors (i.e. electron confinement regions) are not shown because the control disclosed herein is applicable to other technologies with or without coupler donors. Since the CNOT gates are characterised and GRAPE sequences determined, the scheduling of the N_{g} steps and locations of the CNOT gates to be implemented according to the QEC code can be worked out ahead of time.

FIG. 18b illustrates the semi-parallel application of grape sequences G₁-G₆ where G₂ and G₅ belong to the first set 1801 of CNOT gates, G₃ and G₆ belong to the second set 1802 of CNOT gates, and G₁ and G₄ belong to the third set 1803 of CNOT gates.

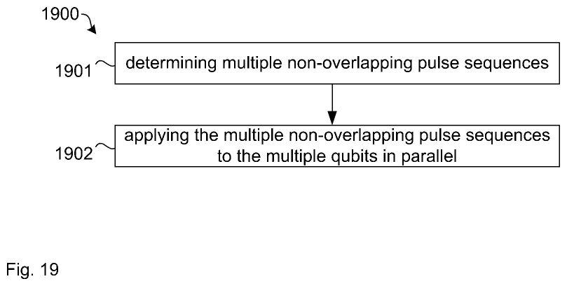

FIG. 19 illustrates a method 1900 for operating a quantum processor. Method 1900 commences by determining 1901 multiple non-overlapping pulse sequences. As described above, each pulse sequence is configured to operate one or more of the multiple qubits selected by the respective site in the lattice. In other words, the sequence is designed such that it operates on exactly those qubits or pairs of qubits with a distance for which this sequence was designed. While it is generally not known which qubits are at which distance as it is hard to measure lattice sites of donor atoms, the multiple sequences together should cover the practically relevant combinations. This also means that some qubits may not be controlled and left unused because they have a highly unlikely lattice site that was not considered when designing the control sequences. Again, determining the multiple non-overlapping pulse sequences is based on possible discrete values of the respective site in the lattice as described above. Finally, the quantum processor applies 1902 the multiple non-overlapping pulse sequences to the multiple qubits in parallel to thereby operate more than one of the multiple qubits in parallel. In parallel in this context means that there is only an insignificant difference between the sequences with respect to their start times and with respect to their end times in the sense that the sequences start at about the same time and end at about the same time, such that phase errors between the qubits are relatively small. In parallel does therefore not necessarily mean that the physical pulse signal of all sequences are generated at the same time.

It is noted that the solutions disclosed herein are potentially application to a range of different quantum computer architectures based on, for example, quantum dots, superconducting qubits, ion traps and phosphorous donors in silicon.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A quantum processor comprising:
an array of multiple source lines, drain lines and gate lines intersecting each other to define multiple processor cells;
each of the multiple processor cells comprising a first qubit, a second qubit and an electron confinement region disposed between the first qubit and the second qubit,
a control circuit to control loading and unloading of an electron into the electron confinement region, wherein
the loading of the electron into the confinement region enables exchange interaction between electrons of the first qubit and the second qubit, and
the unloading of the electron out of the electron confinement region suppresses exchange interaction between the electrons of the first qubit and the second qubit.

2. The quantum processor of claim 1, wherein a distance between the first qubit and the second qubit is greater than the range of exchange interaction between the electrons of the first qubit and the second qubit.

3. The quantum processor of claim 2, wherein the distance between the first qubit and the second qubit is greater than 15 nm.

4. The quantum processor of claim 1, wherein a distance between the first qubit and the second qubit is less than twice the range of exchange interaction between the electrons of the first qubit and the second qubit.

5. The quantum processor of claim 1, wherein a distance between either qubit and the electron confinement region is less than the range of exchange interaction between the electron loaded into the electron confinement region and the electrons of either qubit.

6. The quantum processor of claim 1, wherein a distance between the first qubit and the electron confinement region is greater than the distance between the electron confinement region and the second qubit.

7. The quantum processor of claim 1, wherein the first qubit and the second qubit are formed by respective donor atoms.

8. The quantum processor of claim 7, wherein strain is applied to reduce variations in exchange coupling due to placement variations of the donor atoms.

9. The quantum processor of claim 1, wherein the first qubit and the second qubit are formed by respective quantum dots.

10. The quantum processor of claim 1, wherein the electron confinement region is formed by a donor atom or a quantum dot.

11. The quantum processor of claim 1, wherein quantum information is stored in the electron spin of the first qubit and the second qubit.

12. The quantum processor of claim 1, wherein quantum information is stored in the electron spin of first qubit and the second qubit.

13. The quantum processor of claim 1, wherein hyperfine interaction facilitates a transfer of quantum information between the electrons and nuclei of the respective first qubit and second qubit.

14. The quantum processor of claim 1, wherein the first qubit is configured as an ancilla qubit and the second qubit is configured as a data qubit to perform quantum error correction.

15. The quantum processor of claim 1, further comprising a tunnelling reservoir device to facilitate the loading of the electron into the electron confinement region by tunnelling of the electron from a source electrode into the electron confinement region and to facilitate the unloading of the electron out of the electron confinement region by tunnelling of the electron from the electron confinement region into a drain electrode.

16. The quantum processor of claim 15, wherein the tunnelling reservoir device is a single electron transistor.

17. The quantum processor of claim 1, wherein the control circuit is configured to operate the quantum processor at a frequency that is higher than the frequency of dipole interactions between the first qubit and the second qubit.

18. The quantum processor of claim 17, wherein the control circuit is configured to operate the quantum processor at a frequency of at least 1 MHz.

19. The quantum processor of claim 1, wherein the first qubit and the second qubit remain loaded with an electron during operation of the quantum computer.

20. The quantum processor of claim 1, wherein the first qubit and the second qubit of the multiple processor cells form multiple qubits and the multiple qubits are located at respective sites in a lattice and the control circuit is adapted to perform a method comprising:
determining multiple non-overlapping pulse sequences, each pulse sequence being configured to operate one or more of the multiple qubits selected by the respective site in the lattice, wherein determining the multiple non-overlapping pulse sequences is based on possible discrete values of the respective site in the lattice; and
applying the multiple non-overlapping pulse sequences to the multiple qubits in parallel to thereby operate more than one of the multiple qubits in parallel.

21. The quantum processor of claim 20, wherein determining the multiple non-overlapping pulse sequences is based on pulse engineering.

22. A method for operating a quantum computer, the method comprising:
loading of an electron into a confinement region disposed between a first qubit and a second qubit to enable exchange interaction between electrons of the first qubit and the second qubit; and
unloading of the electron out of the electron confinement region to suppress exchange interaction between the electrons of the first qubit and the second qubit.
